(19) United States
(12) Patent Application Publication
(10) Pub. No.: US 2014/0284611 A1
(43) Pub. Date: Sep. 25, 2014

(54) SEMICONDUCTOR LIGHT-EMITTING DEVICE AND METHOD FOR MANUFACTURING THE SAME

(71) Applicant: KABUSHIKI KAISHA TOSHIBA, Tokyo (JP)

(72) Inventors: Kazuhiro AKIYAMA, Kanagawa (JP); Shuji ITONAGA, Kanagawa (JP)

(73) Assignee: KABUSHIKI KAISHA TOSHIBA, Tokyo (JP)

(21) Appl. No.: 14/017,233

(22) Filed: Sep. 3, 2013

(30) Foreign Application Priority Data
Mar. 25, 2013 (JP) 2013-063039

(51) Int. Cl. H01L 33/32

(52) U.S. Cl. CPC H01L 33/32
USPC 257/76; 438/46

(57) ABSTRACT

According to one embodiment, a method for manufacturing a semiconductor light-emitting device includes growing a semiconductor film including a group III nitride semiconductor on a silicon substrate, dividing the grown semiconductor film into a plurality of sections by selectively removing the semiconductor film, forming an aluminum film to cover the semiconductor film, removing the aluminum film selectively, oxidizing the remained aluminum film, and removing the silicon substrate.

### CROSS-REFERENCE TO RELATED APPLICATION

This application is based upon and claims the benefit of priority from Japanese Patent Application No. 2013-063039, filed Mar. 25, 2013, the entire contents of which are incorporated herein by reference.

### FIELD

Embodiments described herein relate generally to a semiconductor light-emitting device and a method for manufacturing the same.

### BACKGROUND

Recently, a light emitting diode (LED) have been developed using a group III nitride semiconductor. Such an LED is manufactured by forming a multi-layered body which is configured of a semiconductor layer such as a gallium nitride layer (GaN layer) on a substrate for crystalline, epitaxial, growth of the multi-layered body thereon, covering the multi-layered body with a passivation film, encapsulating the multi-layered body in a resin, and then, removing the underlying substrate which is provided for epitaxial growth of the crystalline multi-layered body.

### DESCRIPTION OF THE DRAWINGS

FIG. 1 is a cross-sectional view illustrating a semiconductor light-emitting device according to one embodiment.

FIG. 2 is a graph illustrating a composition distribution of the components of a passivation film in which a position of a thickness direction in the passivation film is shown on a horizontal axis and an aluminum concentration and an oxygen concentration are shown on vertical axes.

FIGS. 3A to 3C are cross-sectional views illustrating a process of a method for manufacturing a semiconductor light-emitting device according to another embodiment.

FIGS. 4A to 4C are cross-sectional views illustrating the process of the method for manufacturing a semiconductor light-emitting device according to another embodiment.

FIGS. 5A to 5C are cross-sectional views illustrating the process of the method for manufacturing a semiconductor light-emitting device according to another embodiment.

### DETAILED DESCRIPTION

According to embodiments described herein, there is provided a semiconductor light-emitting device manufacturable with good yield and a method for manufacturing the same.

In general, according to one embodiment, a semiconductor light-emitting device includes: a semiconductor film including a group III nitride semiconductor; an electrode which is connected to a first face of the semiconductor film; a passivation film which covers an end face of the semiconductor film and a region other than the electrode in the first face and is configured of insulating materials including aluminum and oxygen; and a sealing resin which covers the first face of the semiconductor film and a side face of the electrode and leaves exposed a second face of the semiconductor film. The aluminum concentration of the passivation film adjacent to the semiconductor film is higher than an aluminum concentration of the passivation film which comes into contact with the sealing resin.

According to another embodiment, a method for manufacturing a semiconductor light-emitting device includes: growing a semiconductor film including a group III nitride semiconductor on a silicon substrate; dividing into a plurality of sections by selectively removing the semiconductor film; forming an aluminum film to cover the semiconductor film; selectively removing the aluminum film; oxidizing the remained aluminum film; and removing the silicon substrate.

Hereinafter, embodiments will be described with reference to drawings.

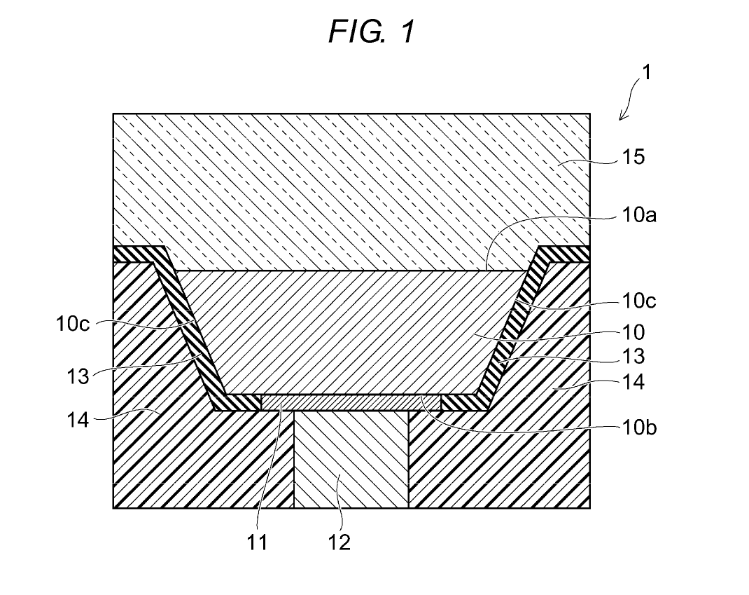

FIG. 1 is a cross-sectional view illustrating a semiconductor light-emitting device according to one embodiment.

A semiconductor film 10 is provided in a semiconductor light-emitting device 1 according to one embodiment, as shown in FIG. 1. The semiconductor film 10 is a semiconductor film including a group III nitride semiconductor such as gallium nitride (GaN), and is formed by sequentially forming a plurality of layers including a light-emitting layer (not shown). An upper face 10a of the semiconductor film 10 is a generally flat surface from which light is output. The lower face 10b of the semiconductor film 10 is divided into two areas by steps (not shown), and each area is flat. Furthermore, only one area divided by steps is shown in FIG. 1, since the other area is located in front of the section of the device shown on the page. In addition, an end face 10c of the semiconductor film 10 inclines at an angle determined by the orientation of a plane of the crystal of the semiconductor film 10.

A rewiring layer 11 which is configured of copper (Cu), for example, is provided on the lower face 10b of the semiconductor film 10, and is connected to a portion of the semiconductor film 10. An electrode 12 which is configured of copper, for example, is provided on a lower face of the rewiring layer 11, and is connected to the rewiring layer 11. Furthermore, two sets of a rewiring layer 11 and an electrode are provided in the semiconductor light-emitting device 1, one as a p-side electrode and one as an n-side electrode. The p-side and n-side electrodes are insulated from each other and connected to the two different areas divided by steps in the lower face of the semiconductor film 10, respectively. However, only one group of the rewiring layer 11 and the electrode 12 is shown in FIG. 1.

Moreover, a passivation film 13 is provided on the lower face 10b and the end face 10c of the semiconductor film 10. The passivation film 13 is configured of insulating materials including aluminum (Al) such as aluminum oxide (AlxOy). The passivation film 13 is not provided on the area of the semiconductor film 10 which is connected to the rewiring layer 11 at the lower face 10b of the semiconductor film 10, and thus, is not interposed between the semiconductor film 10 and the rewiring layer 11. In addition, the passivation film 13 extends along the end face 10c of the semiconductor film 10, and the edge extends past the upper face 10a of the semiconductor film 10.

A sealing resin 14 which is configured of epoxy resin, for example, is provided below the passivation film 13, i.e., the passivation film extends between the semiconductor film 10 and the sealing resin 14. The sealing resin 14 covers the portion of the rewiring layer 11 not connected to the electrode 12, the side faces of the electrode 12, and the adjacent surface of the passivation layer 13.

A phosphor film 15 which is configured of resin materials with dispersed phosphor (not shown) is provided on the upper face 10a of the semiconductor film 10. The phosphor film 15 covers the upper face 10a of the semiconductor film 10 and the portion of the passivation film 13 extending above the upper face 10a of the semiconductor layer 10.

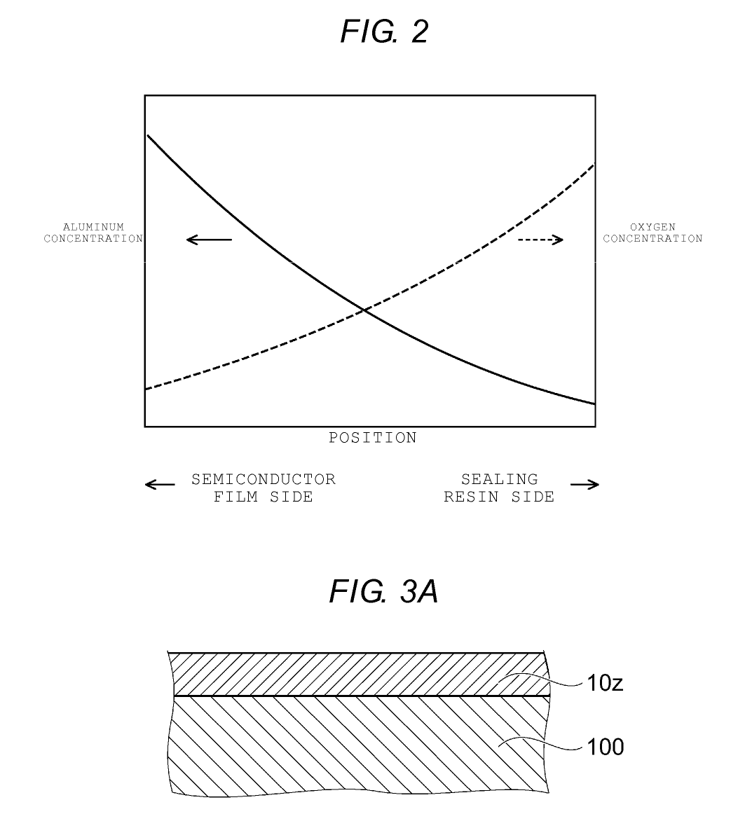

FIG. 2 is a graph illustrating a composition distribution of the passivation film in which a position of a thickness direction in the passivation film is shown on a horizontal axis and an aluminum concentration and an oxygen concentration is shown on the vertical axes.

As shown in FIG. 2, the composition is inclined along the film thickness direction in the passivation film 13, therefore, approaching the semiconductor film 10, the aluminum concentration becomes higher and the oxygen concentration becomes lower, either in the AlxOy compound, and/or the concentration of free (un-reacted) oxygen or aluminum in the film. Approaching the sealing resin 15, the aluminum concentration becomes lower and the oxygen concentration becomes higher, in the aluminum oxide compound. Accordingly, the aluminum concentration of passivation film which comes into contact with the semiconductor film 10 in the passivation film 13 is higher than the aluminum concentration of the passivation film which comes into contact with the sealing resin 15. However, the portion of the passivation film which comes into contact with the semiconductor film 10 is an insulator.

Subsequently, a method for manufacturing a semiconductor light-emitting device according to the embodiment will be described.

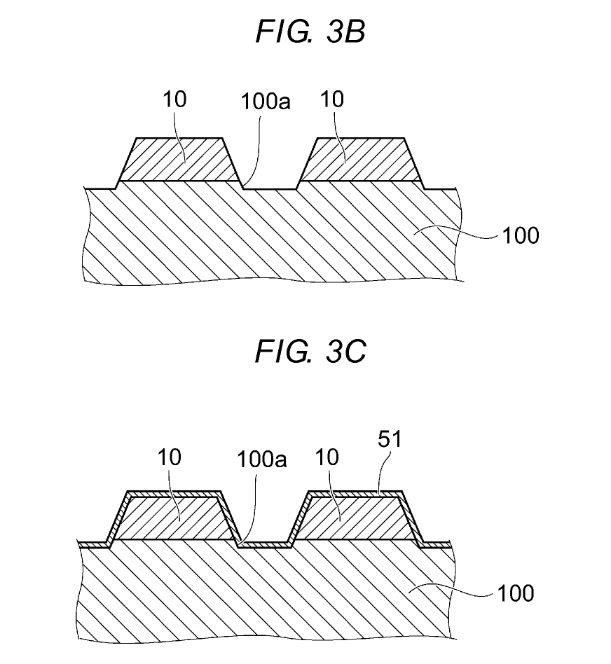

FIGS. 3A to 3C, FIGS. 4A to 4C and FIGS. 5A to 5C are cross-sectional views illustrating processes of the method for manufacturing a semiconductor light-emitting device according to the embodiment.

Furthermore, for convenience of the description, upper and lower directions in FIGS. 3A to 3C, FIGS. 4A to 4C and FIGS. 5A to 5C are in reverse to the upper and lower directions in FIG. 1.

First, as shown in FIG. 3A, a silicon wafer 100 is provided as a substrate for epitaxial crystal growth of the GaN semiconductor layers thereon. Next, a semiconductor film 10z containing a group III nitride semiconductor such as gallium nitride (GaN) is grown epitaxially on the silicon wafer 100. The semiconductor film 10z is a continuous film. Additionally, an electrode layer (not shown) is formed where needed on the semiconductor film 10z.

As shown in FIG. 3B, the semiconductor film 10z is divided into a plurality of semiconductor films 10 by selectively removing portions of the semiconductor film 10z by pattern etching of the semiconductor film 10z. A groove 100a is formed by overetching into the silicon wafer 100.

As shown in FIG. 3C, an aluminum film 51 is formed on the portion of the silicon wafer 100 exposed and etched during the etching of the semiconductor film 10z and the semiconductor film 10, by depositing aluminum (Al) using a sputtering method, an evaporation method or a plating method, for example.

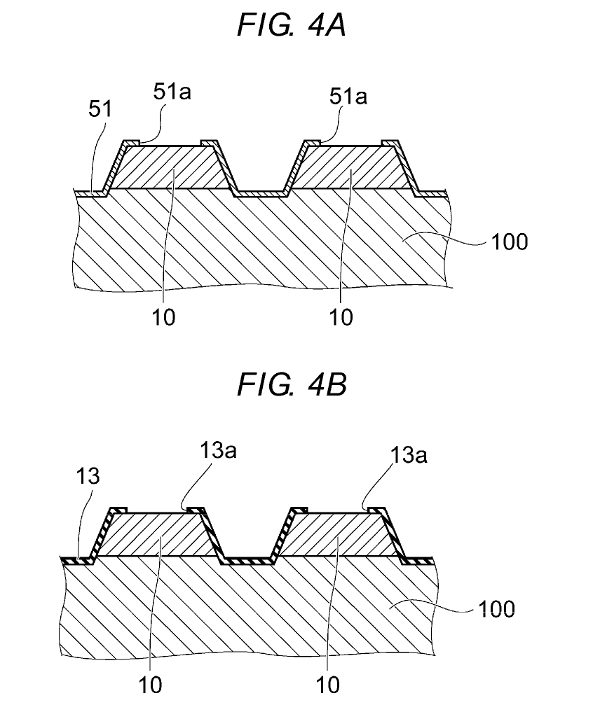

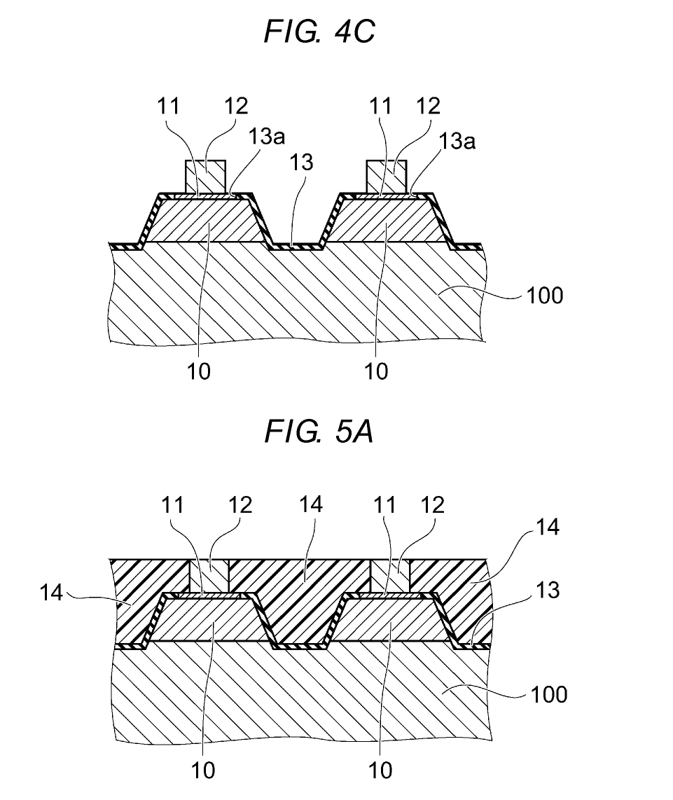

As shown in FIG. 4A, an opening 51a is formed in the aluminum film 51 to expose the semiconductor film 10 by selectively removing the aluminum film 51. The semiconductor film 10 is thus locally exposed in the opening 51a. The selective removing of the aluminum film 51 may be performed by wet etching using a mixing solution such as H₃PO₄, HNO₃, or CH₃COOH as an etching solution, for example through a patterned mask. Otherwise, the opening 51a may be formed using a lift-off method. If a resist pattern for lift-off is formed by a lithography method, a part of the aluminum film is removed by removing the resist pattern after depositing aluminum onto the resist.

As shown in FIG. 4B, the aluminum film 51 is oxidized by performing oxidation of the remaining aluminum film 51. Accordingly, the aluminum film 51 is converted into an insulative passivation film 13 comprising aluminum oxide. An opening 13a, which is derived from the opening 51a of the aluminum film 51, remains in the passivation film 13. The film thickness of the passivation film 13 is larger than the film thickness of the aluminum film 51 due to volume expansion of the film caused by the addition of oxygen during the oxidization step.

The oxidation of aluminum may be performed by chemical conversion coating, oxidizing with plasma or oxidizing with heat, for example. As a chemical conversion coating method, a method such as an alkali-chromate method or a phosphorus zinc method may be used. Oxidizing with plasma may be performed by oxidizing the aluminum film 51 in an oxygen plasma atmosphere. Oxidizing with heat may be performed by heating the aluminum film 51 in an oxygen atmosphere. In all cases, the oxygen concentration becomes lower and the aluminum concentration becomes higher in the depth direction of the passivation film 13 after oxidizing, since oxygen enters the passivation film mainly from the exposed face of the aluminum film 51, and the opposed face of the face which comes into contact with the semiconductor film 10 may be configured to have less oxygen than the face of the aluminum film 51 exposed to the oxygen source.

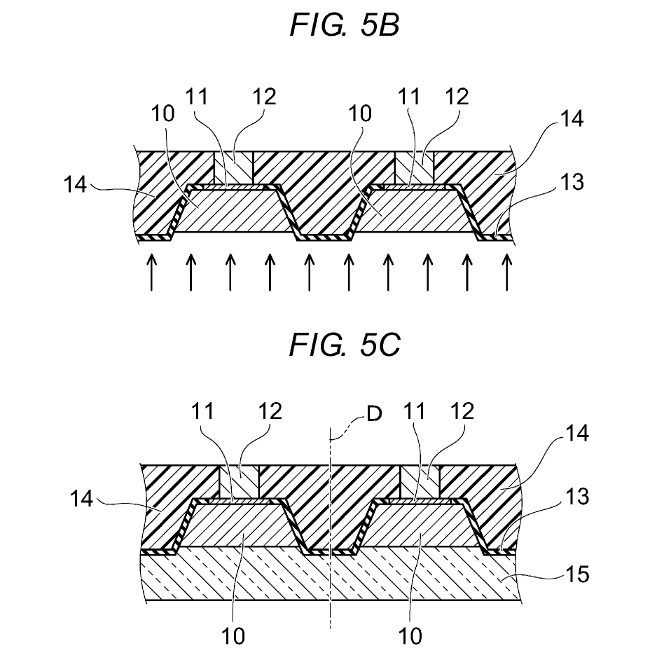

Next, as shown in FIG. 4C, the rewiring layer 11 configured of copper (Cu) is formed inside of the opening 13a, for example, and an electrode 12 configured of copper is formed on the rewiring layer 11, for example. Two sets of a rewiring layer 11 and electrode 12 are formed on a semiconductor film 10. Only one set is shown in FIG. 4C and FIGS. 5A to 5C.

As shown in FIG. 5A, a resin material such as epoxy resin is applied so as to cover the semiconductor film 10, the passivation film 13, the exposed portions of the rewiring layer 11 and the sides of the electrode 12, that is, structures on the silicon wafer 100. The passivation film 13 configured of the resin material and silicon oxide is baked by performing heating. The sealing resin 15 is formed by caking the resin material.

Subsequently, as shown in FIG. 5B, the silicon wafer 100 is removed. The semiconductor film 10 and the passivation film 13 are exposed by the removal of the silicon wafer 100. The removing of the silicon wafer 100 may be performed by wet etching or dry etching. Moreover, grinding the silicon wafer 100 and thinning the silicon wafer 100 may be performed before wet etching or dry etching thereof for removal.

For example, fluonitric acid may be used as an etching solution for wet etching. Since the passivation film 13 is configured of aluminum oxide and is not etched in fluonitric acid, a high selection ratio, i.e., high selectivity to silicon, may be realized between the silicon wafer 100 and the passivation film 13. The etching solution is not limited to fluonitric acid, and the material which is capable of realizing a high selection ratio of etching between silicon and aluminum oxide may be used.

On the other hand, sulfur hexafluoride (SF₆) may be used as an etching gas for dry etching of the silicon wafer 100, which may be performed as a plasma etch. Since minimal etching of the passivation film 13 configured of aluminum oxide occurs by sulfur hexafluoride, a high selection ratio of etching may be realized between the silicon wafer 100 and the passivation film 13. The etching gas is not limited to sulfur hexafluoride, and the material which is capable of realizing a high selection ratio of etching between silicon and aluminum oxide maybe used.

As shown in FIG. 5C, the resin material with dispersed phosphor is applied on the exposed faces of the semiconductor film 10 and the passivation film 13, and baked. Thus, the phosphor film 15 is formed.

The structure configured of the phosphor film 15, the semiconductor film 10 and the sealing resin 14 is diced along a dicing line D. Thus, the light emitting device structure is fixed in each piece of the semiconductor film 10, and the semiconductor light-emitting device 1 illustrated in FIG. 1 is manufactured.

Next, effects of the embodiments will be described.

According to the embodiments, since the passivation film 13 is formed by aluminum oxide, as the silicon wafer 100 is removed, a selection ratio of etching can be easily secured between the silicon wafer 100 and the passivation film 13 in the process shown in FIG. 5B. Accordingly, the silicon wafer 100 can be effectively removed by a simple method.

According to the embodiments, the aluminum film 51 is formed on the semiconductor film 10 in the process shown in FIG. 3C, the opening 51a is formed in the aluminum film 51 in the process shown in FIG. 4A, and the passivation film 13 which is configured of aluminum oxide is formed by oxidizing the aluminum film 51 in the process shown in FIG. 4B thereafter. The opening 13a into which the rewiring layer 11 and the electrode 12 are inserted can be simply formed in the process shown in FIG. 4C.

On the contrary, a processing method which is capable of realizing a selection ratio of etching between a group III nitride semiconductor and aluminum oxide is limited to a particular method such as ion milling, thus limiting the processing options when the opening 13a is formed by processing the passivation film after forming the passivation film 13 as the aluminum oxide. Consequently, forming the opening 13a in the passivation film 13 is difficult by a processing device using a general semiconductor process.

Similarly, according to the embodiments, the opening 51a is formed in the aluminum film 51, and thus the opening 13a was easily formed in the aluminum layer prior to it being oxidized to form the passivation film 13 configured of aluminum oxide. In addition, the silicon wafer can be easily removed by forming the passivation film 13 of aluminum oxide. As a result, the semiconductor light-emitting device 1 with high productivity can be manufactured.

A passivation film 13 which is formed by silicon-based insulating materials such as silicon nitride (SiN), silicon carbo-nitride (SiCN), or silicon oxide (SiO), is also considered. However, resistance of silicon nitride (SiN) or silicon carbo-nitride (SiCN) is low to an etching gas such as SF₆ to remove silicon, therefore the selection ratio of etching does not become sufficient. On the other hand, resistance of silicon nitride (SiN) is low to an etching solution such as fluonitric acid to remove silicon, and thus the selection ratio of etching does not become sufficient.

If silicon based passivation layers are used, during etching of the silicon wafer 100, silicon may remain in the passivation film 13 due to the insufficient selectivity of silicon to silicon oxide, silicon nitride, etc. As a result, if the passivation film 13 is formed of silicon-based insulating materials, a combination of composition of the passivation film 13 and the removing method of the silicon wafer 100 is needed to select carefully, adding to the complexity of the removal process.

According to the embodiments, the aluminum concentration of the portion of the passivation layer 13 which comes into contact with the semiconductor film 10 is the highest concentration of the film layer, since the aluminum composition of the passivation film 13 increases in the film thickness direction. Aluminum as a group III element causes composition to be inclined, therefore, integrity increases between the semiconductor films 10 which is configured of the passivation film 13 and the group III nitride semiconductor, and adhesive properties between the passivation film 13 and the semiconductor film 10 become high.

An example in which the passivation film 13 which is configured of aluminum oxide is formed by performing oxidation to the aluminum film 51 is shown in the embodiments described above, moreover, the passivation film 13 configured of aluminum acid nitride (AlON) may be formed by performing both of oxidation and nitridation with respect to the aluminum film 51.

According to the embodiments as described above, a semiconductor light-emitting device with high productivity and a method for manufacturing the same may be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A method of manufacturing a semiconductor light-emitting device, the method comprising:
growing a semiconductor film including a group III nitride semiconductor on a silicon substrate;
dividing the semiconductor film into a plurality of sections by pattern removal of portions of the semiconductor film;
forming an aluminum film to cover the semiconductor film;
selectively removing portions of the aluminum film to form opening where the semiconductor film is exposed;
oxidizing the remaining aluminum film;
forming an electrode in the opening and on the upper face of the semiconductor film; and
removing the silicon substrate by etching.

2. The method of manufacturing a semiconductor light-emitting device of claim 1, further including the step of removing the silicon substrate using fluonitric acid as the etchant.

3. The method of manufacturing a semiconductor light-emitting device of claim 1, further including the step of removing the silicon substrate using sulfur hexafluoride as the etchant.

4. The method of manufacturing a semiconductor light emitting device of claim 1, wherein the step of oxidizing the remaining aluminum film result in a gradient in the relative concentration of oxygen in the depth direction of the aluminum film.

5. The method of manufacturing a semiconductor device of claim 4, wherein the step of oxidizing the remaining aluminum film comprises exposing the aluminum film to oxygen plasma.

6. The method of manufacturing a semiconductor device claim of 4, wherein the step of oxidizing the remaining aluminum film comprises annealing the aluminum film in oxygen ambient.

7. The method of manufacturing a semiconductor device of claim 1, further including the step of exposing the aluminum film to nitrogen ambient and thereby forming a nitride of at least a portion of the aluminum film.

8. The method of manufacturing a semiconductor device of claim 1, further including the step of covering a surface of the oxidized aluminum film with a resin.

9. The method of manufacturing a semiconductor device of claim 8, further including the step of covering a surface of the semiconductor layer with a phosphor containing material.

10. A method for manufacturing a semiconductor light-emitting device, the method comprising:
growing a semiconductor film including a group III nitride semiconductor on a silicon substrate;
dividing semiconductor film on the substrate into a plurality of sections by selectively removing portions of the semiconductor film;
forming an aluminum film over the divided semiconductor film;
selectively removing portions of the aluminum film selectively;
oxidizing the aluminum film; and
removing the silicon substrate.

11. The method according to claim 10, wherein the step of removing the silicon substrate includes wet etching the silicon substrate.

12. The method according to claim 11, wherein the wet etchant comprises fluonitric acid.

13. The method according to claim 10, wherein removing the silicon substrate includes performing dry etching.

14. The method according to claim 13, wherein an etching gas is sulfur hexafluoride.

15. The method of claim 10, further including the step of forming an electrode on an upper face of the semiconductor film in a region where the aluminum film was removed therefrom.

16. The method of claim 10, wherein the step of oxidizing the aluminum film forms a gradient in oxygen concentration in the depth direction of the aluminum film wherein the oxygen content of the film decreases as the distance into the oxidized film from the surface thereof exposed to an oxidizing agent increases.

17. The method of claim 10, further including the step of exposing the aluminum film to a nitriding composition.

18. A semiconductor light-emitting device comprising:
a semiconductor film including a group III nitride semiconductor;
an electrode connected to a first face of the semiconductor film;
a passivation film which covers the first face and side wall of the semiconductor film and which comprises an electrically insulating material including aluminum and oxygen;
an electrode structure extending through the passivation film and contacting a surface of the semiconductor film;
a sealing resin which covers the first face of the semiconductor film and a side face of the electrode and exposes a second face of the semiconductor film,
wherein the aluminum concentration of a section which comes into contact with the semiconductor film in the passivation film is higher than an aluminum concentration of a section which comes into contact with the sealing resin in the passivation film.

19. The semiconductor light-emitting device of claim 18, wherein the passivation film comprises an Aluminum Oxynitride compound.

20. The semiconductor light-emitting device of claim 18, wherein the semiconductor film includes a second face opposed to the first face, and the second face is at least partially covered with a phosphor containing material.
